(19) United States
(12) Patent Application Publication
(10) Pub. No.: US 2008/0176412 A1
(43) Pub. Date: Jul. 24, 2008

(54) Atomic layer deposition system including a plurality of exhaust tubes

(75) Inventor: Kenji Komeda, Tokyo (JP)

Correspondence Address: YOUNG & THOMPSON, 209 Madison Street, Suite 500, ALEXANDRIA, VA, 22314, US

(73) Assignee: ELPIDA MEMORY, INC., Tokyo (JP)

(21) Appl. No.: 12/010,149

(22) Filed: Jan. 22, 2008

(30) Foreign Application Priority Data
Jan. 22, 2007 (JP) 2007-011784

(51) Int. Cl. H01L 21/31; B05C 11/00

(52) U.S. Cl. 438/778; 118/712; 257/E21.24

(57) ABSTRACT

An atomic layer deposition system includes a reaction chamber, a plurality of exhaust tubes communicated to the reaction chamber, a plurality of first vacuum gauges for monitoring the degree of vacuum of the respective exhaust tubes, a second vacuum gauge for monitoring the degree of vacuum of the reaction chamber, and control valves for adjusting the exhaust volume of the exhaust tubes independently of one another. The control valves are controlled based on the pressures measured by the first and second control valves for achieving a uniform flow of the vapor phase reactant.

This application is based upon and claims the benefit of priority from Japanese patent application No. 2007-011784, the disclosure of which is incorporated herein in its entirety by reference.

### BACKGROUND OF THE INVENTION

1. Field of the Invention

The present invention relates to an atomic layer deposition (ALD) system and a method of depositing an insulation film by using an ALD process, and more particularly, to an improvement of the process of depositing the insulation film in the semiconductor device by using an ALD technique.

2. Description of the Related Art

With the improvement of micro-fabrication technology, development of a higher integration density of DRAM devices has been accelerated, to achieve a reduction in the occupied area for cell capacitors in the DRAM device. On the other hand, it is necessary to maintain the capacitance of the capacitors required for operating the DRAM devices. This resulted in the main stream of capacitors having a cylindrical structure or a high-aspect-ratio capacitor insulation film after alteration of the previous generations. In this background, it has become difficult to form a capacitor insulation film having an excellent coating performance while using the conventional CVD (Chemical Vapor Deposition) technique. As an alternative to the CVD technique, an ALD technique has recently been used for depositing the capacitor insulation film. The ALD technique is such that the object insulation film is deposited as a plurality of atomic-level-thickness layers which are repetitively deposited. For instance, when an amorphous aluminum oxide film is to be formed, as shown in FIG. 9, a step (step B) of introducing trimethylaluminum (TMA) as an aluminum source and a step (step E) of introducing ozone (O₃) as an oxidizing agent are alternately performed. Between adjacent source/agent gas introducing steps, an evacuation step (steps D and G) and a purging step (steps A, C and F) using an inert gas (argon (Ar)) are performed so as to avoid a reaction in the vapor phase. The introduced trimethylaluminum (TMA) gas is oxidized only in the status thereof being adsorbed onto the surface of the semiconductor wafer. Therefore, by optimizing the amount of gas adsorbed onto the surface of the substrate, an elaborate capacitor insulation film having an excellent film quality can be formed even with the case of a high-aspect-ratio structure.

On the other hand, in the semiconductor device industry, the price fluctuation is extensive and ceaseless. In order to overcome the competition between the manufactures, reduction in the fabrication costs is essential. In such circumstances, a trend of increasing the size of a semiconductor wafer has been accelerated, whereas formation of a uniform film in the whole area of the semiconductor wafer has become difficult along with the development of the large-size semiconductor wafer.

Particularly, if the aforementioned ALD technique is used to deposit a film, such as capacitor insulation film, onto the bottom portion of the cylindrical holes in the entire area of the semiconductor wafer, it is necessary to equalize the amount of surface adsorption of the vapor phase reactant in the bottom of the cylindrical holes. Therefore, it is necessary to either feed an excessive quantity of vapor phase reactant so as to saturate the amount of surface-adsorbed gas, or to control the feed of gas to be uniform all over the wafer so as to maintain the specified amount of surface-adsorbed gas to reach the saturated amount.

FIG. 10 shows an example of the conventional ALD system for depositing a capacitor insulation film. In FIG. 10, the capacitor insulation film to be formed is an amorphous aluminum oxide film. As an aluminum source for forming the amorphous aluminum oxide, trimethylaluminum (TMA) is used, and as an oxidizing agent, ozone (O₃) is used. The TMA and O₃ are introduced into a reaction chamber or deposition chamber 31 from separate feed tubes 35 and 36, respectively, through a shower head 33. Further, another tube for feeding argon (Ar) is communicated with each of the feed tubes 35 and 36 so that the internal of the feed tubes and reaction chamber 31 may be replaced with an inert gas. Additionally, an exhaust duct 38 is provided to discharge non-reacted gas and undesirable reaction products. This exhaust duct 38 is connected to an evacuation system including a vacuum pump (not shown).

A pressure-control rotary valve 39 is provided on the midway of the passage of the exhaust duct 38. By adjusting the flow passed by the rotary valve 39, the pressure in the reaction chamber 31 can be controlled between 0.133 Pa and 13.3 Pa. Further, a stage heater 34 is provided in the reaction chamber 31. A semiconductor wafer 32 mounted on the stage heater 34 is heated up to a specific temperature suitable for deposition, i.e., filming temperature. The filming temperature is arbitrarily selected within the range between 250° C. and 500° C. in accordance with the type of the capacitor insulation film to be formed and the structure on the surface portion of the semiconductor wafer. After the semiconductor wafer 32 is conveyed into the reaction chamber 31 through a sample carry-in entrance 37, filming process of the amorphous aluminum oxide film is started. The uniformity in the film thickness after the filming process is achieved by controlling the degree of vacuum, filming temperature, gas flow rate, and the like.

In the ALD process as described above, if the optimum amounts of feed gases in the respective steps are different from one another, the flow direction of the gases is changed from step to step. This may cause the problem that those films cannot be formed uniformly in the whole area of the semiconductor wafer. Even if the film thickness on the surface of the semiconductor wafer is uniform, the within-wafer uniformity of the film quality may differ in some cases. Further, in the circumstances in which the tendency of high-aspect-ratio structure is being accelerated for the capacitor insulation film as described above, even if the film thickness and quality are uniform in the upper portion, for example, of the cylindrical hole, the film thickness and quality in the lower portion of the cylindrical hole may be different from those in the upper portion, because the gas may not be fed sufficiently down to the bottom of the cylindrical hole to thereby reduce the coating performance of the film.

In case of using a condition of saturated feed amount, in which an excessive quantity of gas is fed, to solve such a problem, the setup time of step B (or E) in FIG. 9 should be at several tens to several hundreds of seconds, or more than that in some cases. This extremely lowers the processing performance of the ALD system. In order to cope with the problem, a semiconductor manufacturing system is desired which can control the gases to flow uniformly on the whole area of the semiconductor wafer and provide a film having an excellent film quality without using the feed-saturated condition. However, it is difficult to control the gas flow in this way by using the conventional ALD system.

FIGS. 11A and 11B show a top plan view and a sectional view, respectively, of an example of the gas flown in the conventional ALD system. The flow direction of the gas in step B (or E) of the filming process is indicated by an arrow, and the flow rate of gas is represented by the number of arrows. For obtaining an ideal state of the flow distribution, the exhaust duct 38 should be arranged at the center of the reaction chamber 31 and the reaction chamber 31 should have a perfect circular shape. With this configuration, the gas flow will be uniform in all directions. However, in a practical arrangement of the ALD system, key units such as the stage heater 34 and the like are generally installed at the center of the reaction chamber 31. Such being the case, the exhaust duct 38 is often arranged at a location off the center of the reaction chamber 31. Further, the reaction chamber 31 cannot have a perfect circular shape and may have a variety of convex and concave portions, which cause ununiformity in the gas flow. As an example of the configuration solving the above problem, as shown in FIGS. 12A and 12B, some ALD systems include a shield plate 50 in the reaction chamber 31.

The shield plate 50 has therein openings 51 with a variety of diameters for controlling the gas flow within the reaction chamber 31, to thereby control the gas flow. However, this structure assumes only the case of using a standard process condition. If a process condition deviating from the standard condition is adopted, an ununiformity may still occur in the gas flow. FIGS. 13A and 13B show the results of measuring the within-wafer distribution of the thickness in an Al₂O₃ film in both the cases wherein the standard condition (condition A) is used to perform the filming process in the apparatus having the shield plate 50, and wherein the condition (condition B) deviating from the standard condition is used in order to optimize the film quality of the capacitor insulation film. In the standard condition, i.e., condition A, as shown in FIG. 13A, the film thickness is substantially concentrically changed in the within-wafer distribution, by allowing the gas to flow uniformly in the whole area of the semiconductor wafer. On the other hand, in the case of condition B taking into consideration the optimum film quality, as shown in FIG. 13B, the film thickness in the within-wafer distribution is deviated from the concentric distribution to reflect the ununiformity or deviation of the gas flow indicated by an arrow.

If the optimum feed quantity of gas is established, as in the case of FIG. 13B, to improve the film quality of the capacitor insulation film, the thickness uniformity in the within-wafer distribution is likely to be lost. If the loss of uniformity is not acceptable, a different condition may be employed wherein the within-wafer uniformity of the thickness is assured by any means, even if the resultant film quality is inferior.

Patent Publication JP-1988-56914-A1 describes a technique of equalizing the gas flow in the reaction chamber used in the CVD (Chemical Vapor Deposition) system of a semiconductor device fabrication system. In the CVD system described in the publication, a plurality of exhaust tubes are provided in the CVD chamber, wherein each of the exhaust tubes includes a valve to control the volume of the exhaust gas. However, in the CVD system described in this publication, a condition-dependent open/close control of the valve installed in each of the exhaust tubes is not used. For this reason, if this technique is used in the ALD system as described above, under the condition deviating from the standard condition, just as the case where the optimum feed quantity of gas is established to obtain the film quality of the capacitor insulation film, it is essential to perform the open/close control of the valves. Thus, the technique does not provide a desired performance for the ALD system for a variety of different conditions.

### SUMMARY OF THE INVENTION

It is therefore an object of the present invention to provide an ALD system in which the coating performance of the resultant film can be improved by controlling the gas flow in each step of gas introduction, without degrading the processing performance in the filming process using the ALD technique, thereby obtaining a uniform film quality in the whole area of the semiconductor wafer and the cylindrical holes having a higher aspect ratio.

It is another object of the present invention to provide a method of depositing an insulation film in a semiconductor device, wherein the coating performance of the resultant insulation film can be improved by controlling the gas flow in each step in the filming process using the ALD technique to thereby form a uniform film.

The present invention provides an in-line atomic layer deposition (ALD) system for depositing a film by using an ALD process, including: a reaction chamber; a stage arranged in the reaction chamber for mounting thereon a semiconductor wafer; and a plurality of exhaust tubes provided on a periphery of the stage, the exhaust tubes being controlled in an exhaust volume thereof independently of one another, wherein each of the exhaust tubes includes therein a control valve for adjusting the exhaust volume, and the open angle of the control valve is controlled depending on a pressure measured by a first vacuum gauge that is arranged at upstream of the valve to measure a degree of vacuum in the exhaust tube.

The present invention also provides a method for depositing an insulation film by using an in-line atomic layer deposition (ALD) system including a reaction chamber, a stage arranged in the reaction chamber for mounting thereon a semiconductor wafer, and a plurality of exhaust tubes provided on a periphery of the stage, the exhaust tubes each including therein a control valve for adjusting the exhaust volume, the method including the steps of: controlling the exhaust tubes in an exhaust volume thereof independently from one another by using the control valve; and controlling an open angle of the control valve depending on a pressure measured by a first vacuum gauge that is arranged at upstream of the valve to measure a degree of vacuum in the exhaust tube, to thereby control a direction of flow of vapor phase reactant in the reaction chamber.

### BRIEF DESCRIPTION OF THE DRAWINGS

FIGS. 1A and 1B show a top plan view and a sectional view, respectively, of an ALD system according to a first embodiment of the present invention;

FIG. 2 is a system diagram showing the control of a pressure-control rotary valve in the first embodiment;

FIG. 3A is a sectional view showing the setup of open angle of the pressure-control rotary valves in step B (or E) in the first embodiment; and FIGS. 3B and 3C are tables each showing the setup of optimum open angle in steps B and E;

FIG. 4A is a timing chart in the ALD process of the first embodiment; and FIG. 4B is a table showing the open angle of the pressure-control rotary valves in each step of the ALD process;

FIG. 5A is a timing chart in an ALD process in a modified example of the first embodiment; and FIG. 5B is a table showing the open angle of the pressure-control rotary valves in each step of the ALD process;

FIGS. 6A and 6B show a top plan view and a sectional view, respectively, of an ALD system according to a second embodiment of the present invention;

FIGS. 7A and 7B are sectional views each showing the setup of open angle of the pressure-control rotary valves in step B (or E) and in the other steps in the process of the second embodiment;

FIG. 8A is a timing chart in the ALD process used in the second embodiment; and FIG. 8B is a table showing the open angle of the pressure-control rotary valves in each step of the ALD process;

FIG. 9 is a timing chart in an ALD process according to a modified example of the second embodiment;

FIG. 10 is a perspective view showing a conventional ALD system;

FIGS. 11A and 11B show a top plan view and a sectional view, respectively, of the conventional ALD system;

FIGS. 12A and 12B show a top plan view and a sectional view, respectively, of a conventional ALD system having therein a shield plate; and

FIGS. 13A and 13B are diagrams each showing the within-wafer distribution of the thickness of the Al₂O₃ film.

### DETAILED DESCRIPTION OF THE INVENTION

Hereinafter, exemplary embodiments of the present invention will be described in detail with reference to the accompanying drawings. It is to be noted that similar constituent elements are designated by similar reference symbols throughout the drawings for avoiding duplicated description of the similar constituent elements.

### First Embodiment

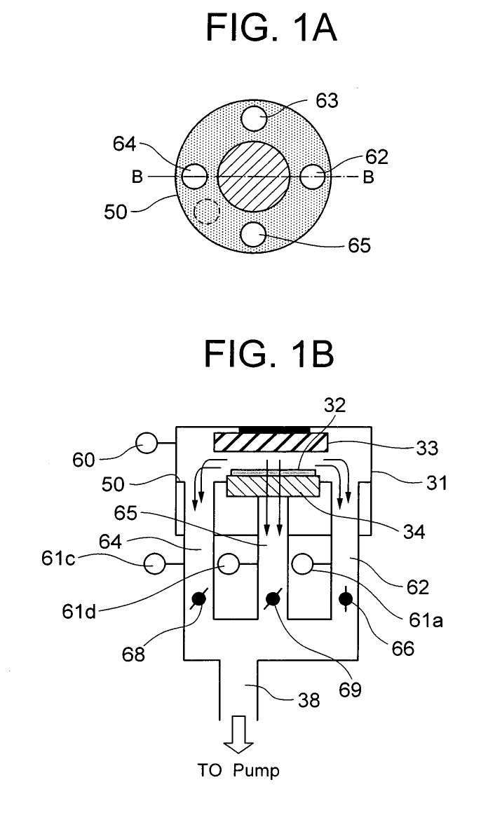

FIGS. 1A and 1B show an ALD system of use in a semiconductor manufacturing system according to a first embodiment of the present invention. FIG 1A is a top plan view of the ALD system, and FIG 1B is a sectional view taken along line B-B shown in FIG 1A. The semiconductor manufacturing system of the present embodiment includes an in-line ALD system which can form a capacitor insulation film by controlling the introduced gas to uniformly flow over the entire area of the semiconductor wafer under substantially all of the filming conditions. The structure of the in-line ALD system will be described first, and thereafter a process for forming the capacitor insulation film by using the ALD system will be described.

The ALD system in the present embodiment includes a shield plate 10 including at least two (four in the example of FIG. 1) exhaust tubes 62 to 65 extending from the shield plate 50 and having a substantially equal diameter. The exhaust tubes 62 to 65 include therein vacuum gauges 61a to 61d, respectively, for controlling the exhaust pressure and pressure-control rotary valves (control valves) 66 to 69, respectively, inserted therein. These exhaust tubes 62 to 65 are coupled together to form an exhaust duct 38 within a reaction chamber 31 or outside the reaction chamber 31, and the exhaust duct 38 is communicated with an evacuation system including a vacuum pump (not shown). The exhaust duct 38 may include a single exhaust duct as shown in FIG. 1B, or include a plurality of separate ducts. In addition, the exhaust tubes 62 to 65 need not be coupled together and may be coupled to the vacuum pump independently of one another.

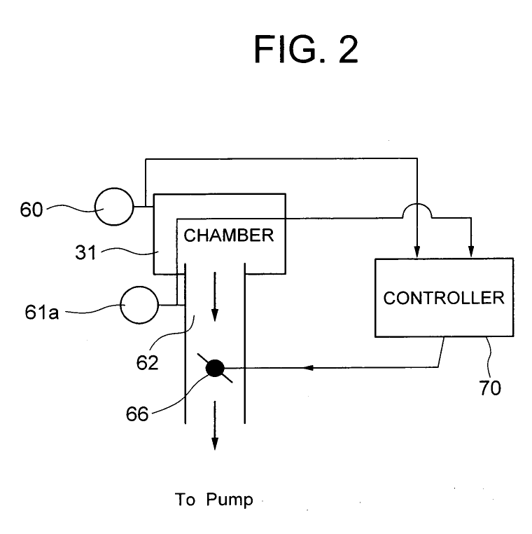

The exhaust pressure within the exhaust tubes 62 to 65 is controlled by adjusting the open angle of the pressure-control rotary valves 66 to 69 so that the pressure measured by the vacuum gauges 61a to 61d installed in the respective exhaust tubes 62 to 65 may become equal to one another. At this stage, the open angle of the pressure-control rotary valves 66 to 69 is set to an optimum angle within the range of 0 to 90 degrees (0% to 100% in the percent notation). For instance, if the setting angle is at 0 degree, the exhaust tube is in a completely closed state (0%), and if the setting angle is at 90 degrees, the exhaust tube is in a fully open state (100%). FIG. 2 is a system diagram schematically showing part of the ALD system shown in FIG. 1. As shown in FIG. 2, the degree of vacuum in the reaction chamber 31 is monitored by a vacuum gauge 60 and the pressure measured by the vacuum gauge 60 is delivered to a controller 70. Further, the pressure measured by the vacuum gauge 61a that monitors the exhaust pressure in the exhaust tube 62 is also delivered to the controller 70 in a similar manner. The controller 70 controls the pressure measured by the vacuum gauge 60 to have a preset value, and adjusts the open angle of the pressure-control rotary valve 66 so that the vacuum gauge 61a represents the same value as those indicated on the vacuum gauges 61b to 61d that monitor the other exhaust tubes. In FIG. 2, only the exhaust tube 62 is represented; other exhaust tubes 63 to 65 are also controlled by the controller 70 in a manner similarly to that in the exhaust tube 62.

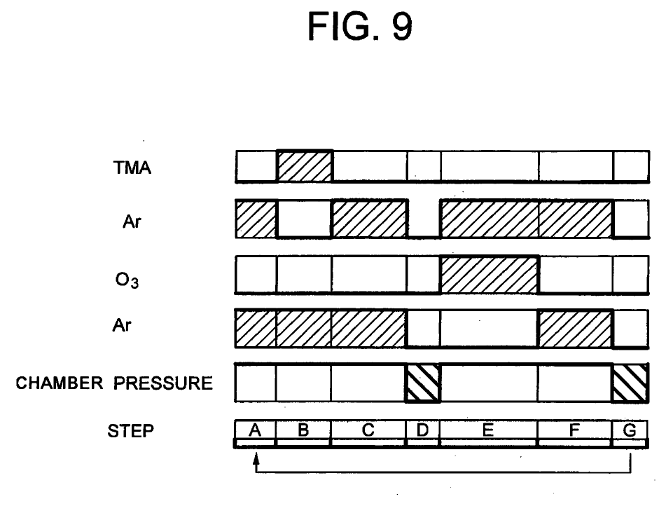

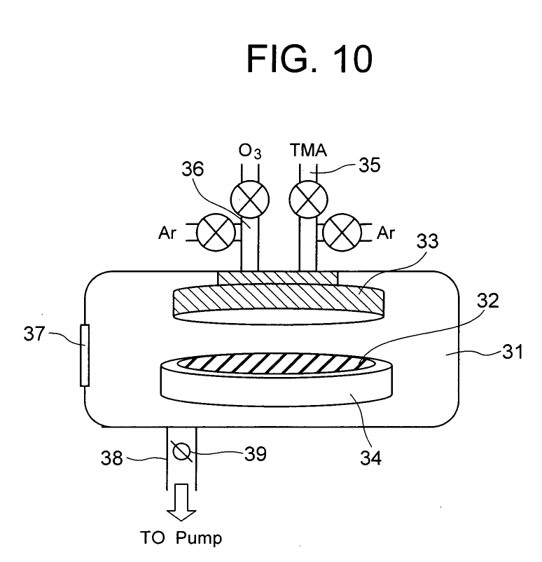

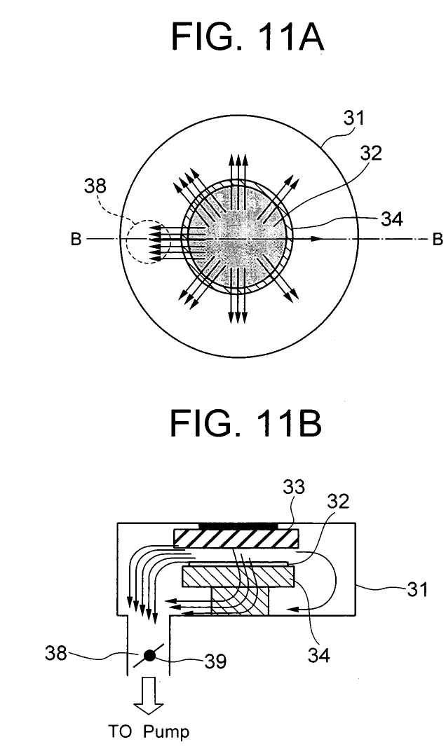

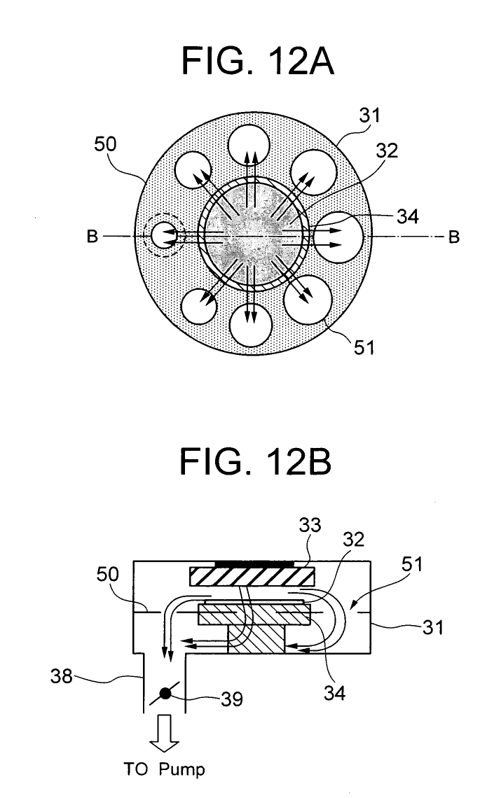

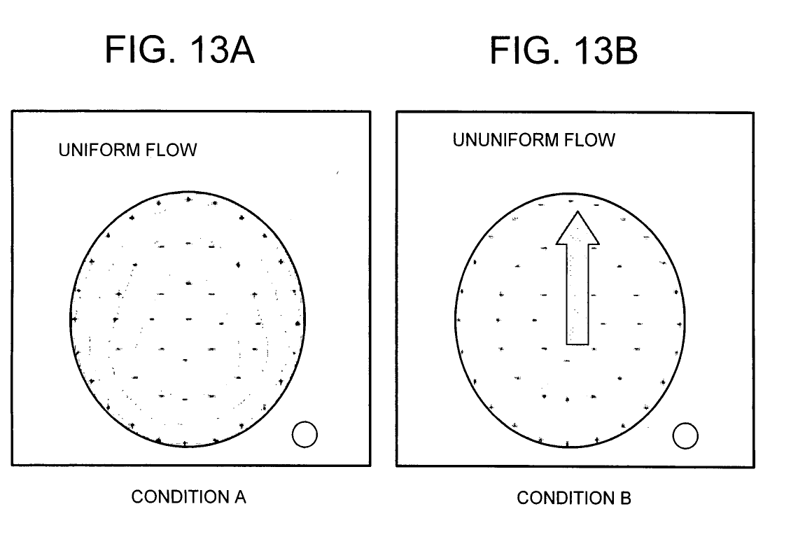

Usually, the ALD process is carried out in accordance with the timing chart shown in FIG. 9. In steps B and E, it is important to control the gas to flow uniformly over the entire surface of the semiconductor wafer 32. On the other hand, in the other steps, it is important to discharge the unreacted gas and the reaction product remaining in the reaction chamber 31 as prompt as possible. In those steps, it is not necessary to control the gas flow. In steps B and E, since different materials are supplied, optimum flow rates of gases differ from one another. Accordingly, although a plurality of exhaust tubes are connected, if the open angle of the pressure-control rotary valves 66 to 69 is fixed to be constant throughout the steps, the gas flow cannot be equalized in all directions. That is, it is necessary for the valves 66 to 69 to be adjusted at an optimum open angle in each step. Hereinafter, the method of forming the capacitor insulation film will be described in detail with reference to the ALD system shown in FIGS 1A and 1B.

As a first stage, optimization of the open angle of the pressure-control rotary valves 66 to 69 is achieved for allowing the gas to uniformly flow in each step. First, the process parameters, such as the filming temperature, degree of vacuum in the reaction chamber 31, and the like, which are necessary for forming the capacitor insulation film are established. Then, the quantity of gas same as the quantity provided by the total flow rate in step B (or E) is supplied into the reaction chamber 31. The open angle of the pressure-control rotary valves of the respective exhaust tubes 62 to 65 is controlled so that the vacuum gauges 61a to 61d of respective tubes 62 to 65 show an equal value. At this stage, the gas to be supplied into the reaction chamber 31 may be a vapor phase reactant (TMA or O₃) used for the actual filming process. Alternatively, an arbitrary gas, for example, an inert gas such as argon gas, O₂ or the like, which is communicated to the ALD system may also be used.

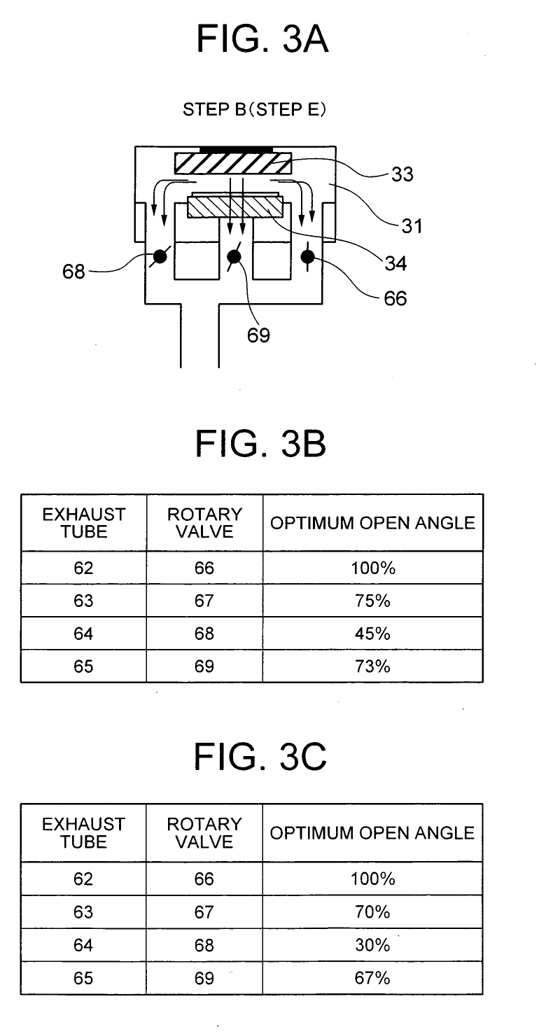

In the first stage, the inert gas such as argon gas is normally used. The degree of vacuum in the reaction chamber 31 is controlled such that the pressure measured by the vacuum gauge 60 that monitors the internal pressure of the reaction chamber 31 becomes the preset value. It is assumed here that the open angles of the respective valves, at which the gas flow in the reaction chamber 31 becomes uniform and the pressure measured by the vacuum gauges 61a to 61d attached to the respective exhaust tubes 62 to 65 become equal to one another, is the optimum open angle. FIGS. 3A to 3C show an example of the optimum open angles in steps B and E. FIG. 3A shows the operating state of the rotary valves; FIG. 3B shows the optimum open angles in step B; and FIG. 3C show the optimum open angles in step E. After the optimum open angles shown in FIGS. 3A to 3C are determined, the optimum open angles shown therein are set as the open angles of the pressure-control rotary valves 66 to 69 in steps B and E. The open angles of those valves in the other steps, in which the gas flow is not controlled, are set in a fully open angle to discharge the residual gas remaining in the reaction chamber 31 as prompt as possible. In an alternative, the open angles in those other steps may be made equal to those used in the subsequent step instead of the fully open angle.

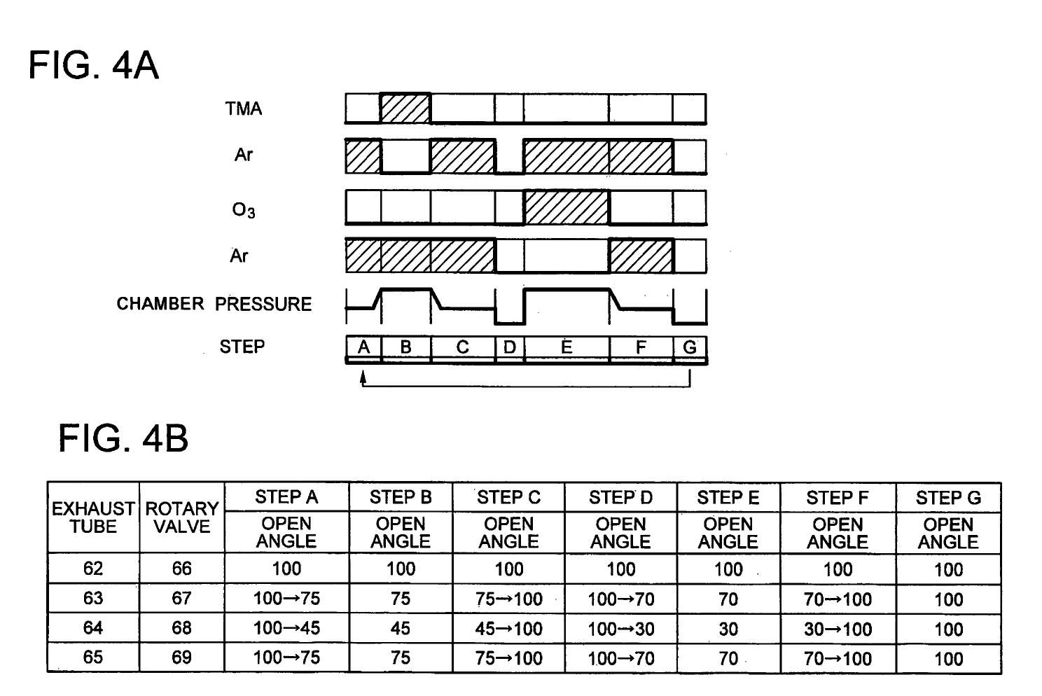

FIG. 4A shows a timing chart in the ALD process of the present embodiment, and FIG. 4B shows the open angles of the pressure-control rotary valves 66 to 69 in each step. About two seconds are needed to finish the change of the open angle of the pressure-control rotary valves 66 to 69. Change of the open angle is carried out in the steps other than steps B and E, which affect the condition of the filming process. The time interval during which the valves are in operation for the change of open angle and thus the gas flow cannot be controlled does not affect the filming characteristics of the ALD system. In the table of FIG. 4B, the columns including therein arrows denote the state of opening/closing posture of the valves. In both steps A and D, the open angle of the valves is changed in the last two seconds within the step processing time, as shown in FIG. 3A. In steps C and F, the open angle of the valves is changed in the first two seconds within the step processing time, as shown in FIG. 3A. It is to be noted that the timing of the change of open angle can be carried out at any stage of the any steps, which do not affect the filming characteristics of the ALD system, except for the steps B and E.

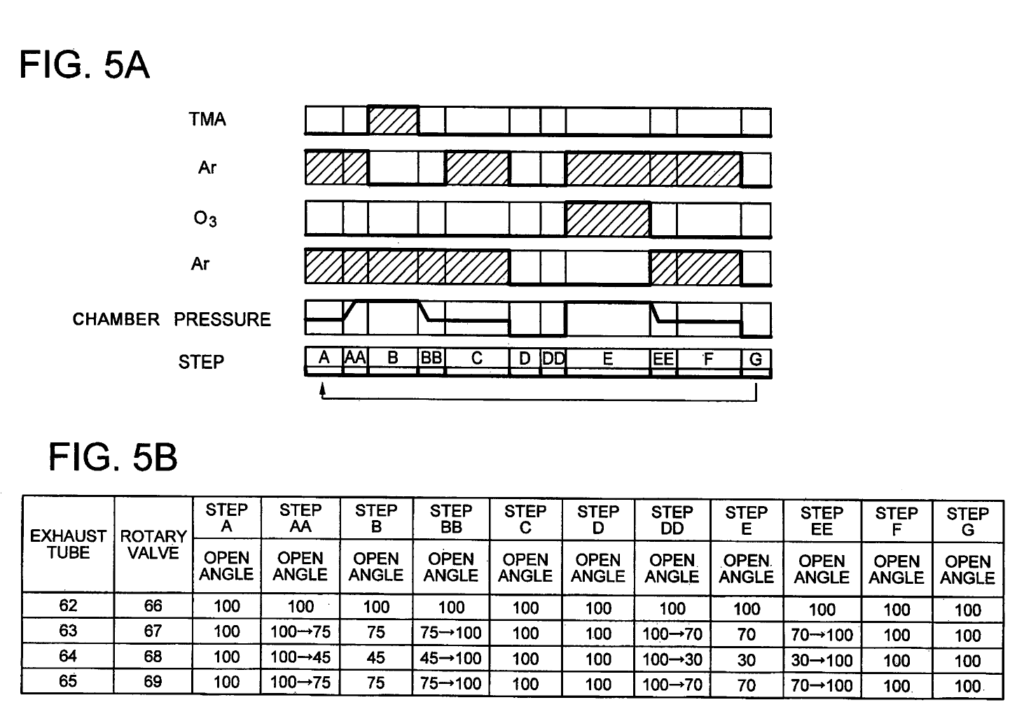

FIGS. 5A and 5B show another example of the timing chart in the ALD process of the present embodiment and the open angles of the pressure-control rotary valves 66 to 69 in each step, respectively. In this example, steps AA, BB, DD and EE, which are provided for the purpose of changing the open angle of the pressure-control rotary valves 66 to 69, are added to the process before or after the subject steps A, B, D, and E. Similarly to the precedent example, the optimum open angle is determined in the first stage, and the thus determined filming conditions are used to proceed onto the second stage, wherein deposition of the film onto the semiconductor wafer is carried out to examine the within-wafer uniformity. In the film deposition onto the semiconductor wafer, the open angle of the pressure-control rotary valves 66 to 69 is changed in synchrony with a shift to the next step so as to obtain the optimum open angle determined in the first stage.

It is to be noted that the procedure for optimizing the open angle of the valves at the first stage may be eliminated. In this case, each time when a step shifts to another, the valves are controlled at the optimum open angle by use of the pressure measured by the vacuum gauges 61a to 61d attached to the respective exhaust tubes 62 to 65 and the pressure measured by the vacuum gauge 60 used for controlling the internal pressure of the reaction chamber 31. In this case, for example, the open angle of a specific one of the pressure-control rotary valves is fixed, and the open angle of each one of the other pressure-control rotary valves is controlled in accordance with the pressure measured by the vacuum gauge of each exhaust tube, thereby examining whether or not the pressure measured by the vacuum gauge in the reaction chamber can be controlled to a desired pressure. If it is possible, the open angle of the specific pressure-control rotary valve is controlled so that the pressure measured by the vacuum gauge in the reaction chamber becomes the preset value. In addition, the other pressure-control rotary valves are controlled in accordance with the pressure measured by a corresponding one of the vacuum gauges.

It is also possible to use the pressure measured by the vacuum gauges 61a to 61d attached to the respective exhaust tubes 62 to 65 and the pressure measured by the vacuum gauge 60 for controlling the internal pressure of the reaction chamber 31, while using the optimum open angles obtained by conducting the first stage as a basis, so as to enable a fine adjustment to consistently obtain the optimum open angles. After the film is deposited onto the semiconductor wafer, the thickness and within-wafer uniformity of the resultant film are evaluated. If a desired result is obtained, the creation or preparation of processing conditions is completed. If the obtained results show a problem, then the degree of vacuum, flow rate of gas, and the like are changed to again perform the first stage, so as to set the optimum open angle of the valves in accordance with the thus changed parameters.

If the valves are to be controlled consistently at the optimum open angle by use of the pressure measured by the vacuum gauges 61a to 61d attached to the respective exhaust tubes 62 to 65 and the pressure measured by the vacuum gauge 60 for controlling the internal pressure of the reaction chamber 31, then each parameter is changed to perform only the second stage. The first and second stages are repeatedly carried out until a desired result can be achieved, which ultimately establishes the optimum processing condition. By using the processing condition created here, the gas can be controlled to uniformly flow in all directions.

In order to control the gas flow in each step, a plurality of exhaust tubes are communicated with the reaction chamber 31 of the in-line ALD system, and further, a vacuum gauge for adjusting the exhaust volume of each exhaust tube and a pressure-control rotary valve 39 are attached to each exhaust tube. The open angle of the pressure-control rotary valve 39 is controlled by the controller 70 so that the vacuum gauges attached to the respective exhaust tubes show an equal value, with the result that the gas flow in the reaction chamber 31 can be uniform in all directions.

### Second embodiment

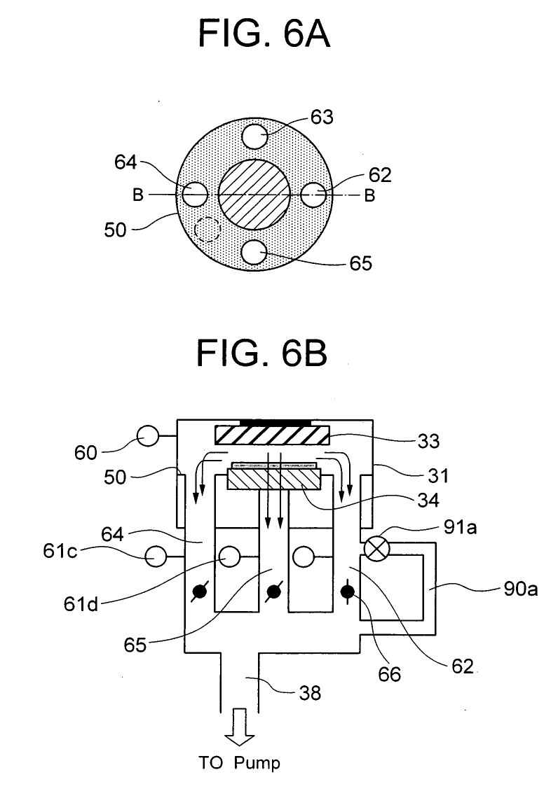

FIGS. 6A and 6B show a top plan view and a sectional view, respectively, of an ALD system in a semiconductor manufacturing system according to a second embodiment of the present invention. FIG. 6B is taken along line B-B shown in FIG. 6A. The configuration of the second embodiment is similar to that of the first embodiment in that a plurality of exhaust tubes 62 to 65 are communicated with the reaction chamber, and the exhaust tubes 62 to 65 include therein the vacuum gauges 61a to 61d, respectively, for adjusting exhaust volume of the exhaust tubes and the pressure-control rotary valves 66 to 69, respectively. The second embodiment is different from the first embodiment in that bypass lines 90a to 90d bypassing the pressure-control rotary valves 66 to 69, respectively, are further provided. Isolation valves 91a to 91d are attached to the bypass lines 90a to 90, respectively. The opening/closing posture of the isolation valves 91a to 91d provides a function similar to that of the pressure-control rotary valves 66 to 69 being fully opened.

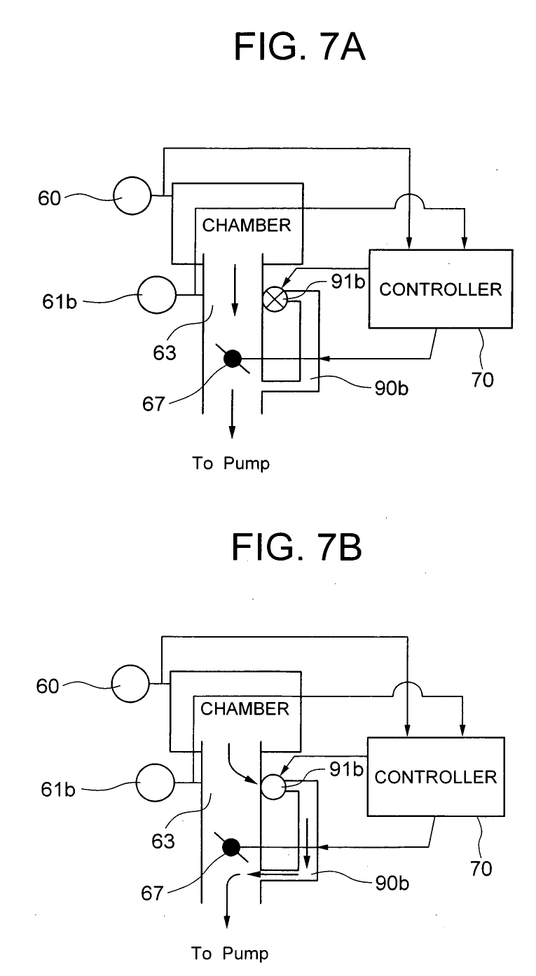

FIG. 6B shows that only the exhaust tube 62 has the bypass line 90a attached thereto. However, in actuality, all the exhaust tubes 62 to 65 have the bypass lines 90a to 90d, respectively, attached thereto. Further, the isolation valves 91a to 91d shown in FIG. 6B are illustrated in the vicinity of an upstream inlet of the bypass lines 90a to 90d, respectively. However, the isolation valves 91a to 91d may be provided at any position of the bypass lines 90a to 90d, respectively. In an alternative, a plurality of isolation valves 91a to 91d may also be provided. FIGS. 7A and 7B each show the control of the pressure-control rotary valves 66 to 69 and the isolation valves 91a to 91d attached to the respective bypass lines 90a to 90d. FIG. 7A represents step B (or E), and FIG. 7B represents the steps other than steps B and E. Specifically, the isolation valves 91a to 91d attached to the respective bypass lines 90a to 90d are controlled by the controller 70 of the pressure-control rotary valves 66 to 69. In each of the steps A, C, D, F and G, in which the gas flow need not be controlled, the opening/closing state of the isolation valves 91a to 91d is controlled instead of controlling the open angle of the pressure-control rotary valves 66 to 69.

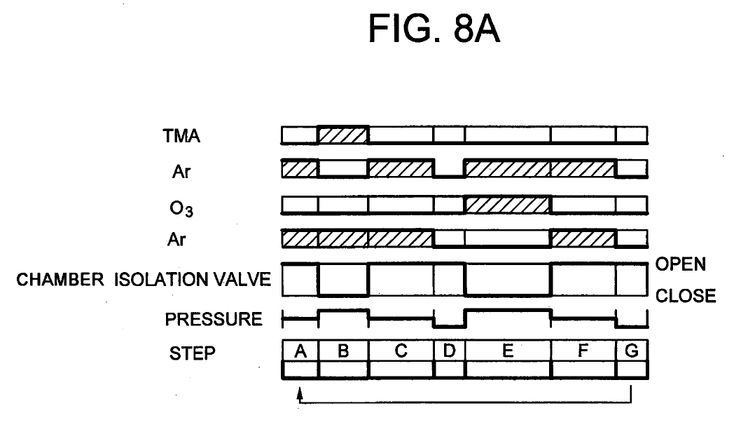

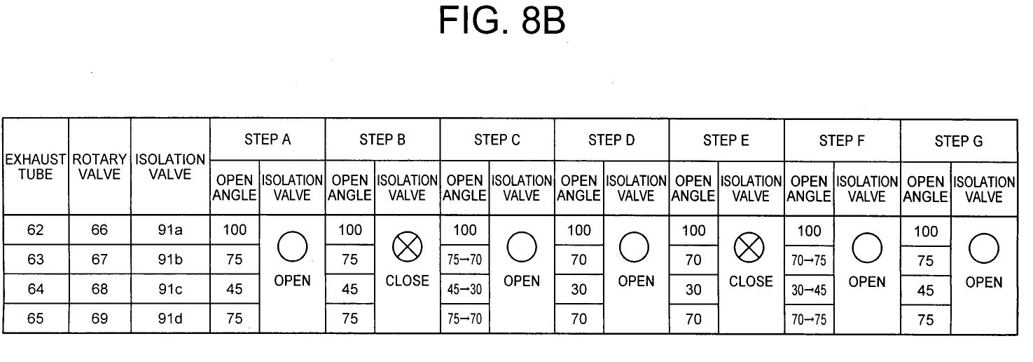

FIGS. 8A shows a timing chart in the ALD process in the second embodiment, and FIG. 8B is a table showing the opening/closing state of both the pressure-control rotary valves 66 to 69 and the isolation valves 91a to 91d. The time length necessary for opening/closing the isolation valves 91a to 91d is somewhat less than one second, which is significantly shorter than the time length need for adjustment of the open angle of the pressure-control rotary valves 66 to 69. After the isolation valves 91a to 91d are opened, the flow resistance of the bypass lines 90a to 90d is low, whereby the gas is discharged through the bypass lines 90a to 90d. While the isolation valves 91a to 91d of the bypass lines 90a to 90d are open, the pressure-control rotary valves 66 to 69 are adjusted at the optimum open angle determined for the subsequent step. Therefore, when the isolation valves 91a to 91d are closed, the pressure-control rotary valves 66 to 69 can immediately shift to the optimum angle for the subsequent step. The method of forming a capacitor insulation film is similar to that described for the first embodiment.

The ALD process in the semiconductor manufacturing system of the above embodiments can provide the following advantages:
(1) In the deposition of a film by using the ALD technique, the gas flow can be controlled in each step, to thereby allow the vapor phase reactant to be uniformly supplied over the entire area of the semiconductor wafer;
(2) Due to the advantage of (1), when the vapor phase reactant is discharged, the discharge speed is enhanced, thereby improving the processing performance of the semiconductor manufacturing system;
(3) Due to the advantage of (1), a condition under which the film quality of the capacitor insulation film is optimized can be used, thereby improving the performance of the semiconductor device, such as a DRAM device, including the film; and
(4) Due to the advantage of (1), the within-wafer characteristics of the capacitor insulation film become uniform, thereby improving the product yield of the semiconductor device, such as a DRAM device.

The present invention may be applied to an in-line ALD system to be used in a semiconductor device manufacturing process, making it possible to manufacture a DRAM device or a DRAM-mixed LSI.

While the invention has been particularly shown and described with reference to exemplary embodiment and modifications thereof, the invention is not limited to these embodiment and modifications. It will be understood by those of ordinary skill in the art that various changes in form and details may be made therein without departing from the spirit and scope of the present invention as defined in the claims.

What is claimed is:

1. An in-line atomic layer deposition (ALD) system for depositing a film by using an ALD process while alternately introducing a plurality of vapor phase reactants, comprising:
a reaction chamber;
a stage arranged in said reaction chamber for mounting thereon a semiconductor wafer; and
a plurality of exhaust tubes provided in a vicinity of a periphery of said stage, said exhaust tubes capable of being controlled in an exhaust volume thereof independently of one another,
wherein each of said exhaust tubes includes therein a control valve for adjusting the exhaust volume, and the open angle of each said control valve is controlled depending on a pressure measured by a first vacuum gauge that is arranged at upstream of each of said control valves to measure a degree of vacuum in each of said exhaust tubes.

2. The in-line ALD system according to claim 1, wherein said control valves each are a pressure-control rotary valve, and an open angle of each said pressure-control rotary valve is controlled to an arbitrary angle in the range of 0 to 90 degrees.

3. The in-line ALD system according to claim 2, wherein the open angle of each said pressure-control rotary valve is further controlled depending on a pressure measured by a second vacuum gauge that measures a degree of vacuum in said reaction chamber.

4. The in-line ALD system according to claim 3, wherein the pressure measured by said second vacuum gauge is controlled so as to be a preset pressure, and the open angle of each said pressure-control rotary valve is controlled so that the exhaust volumes of said exhaust tubes assume an equal value.

5. The in-line ALD system according to claim 4, wherein said exhaust tubes each include a bypass line for bypassing corresponding said pressure-control rotary valve.

6. The in-line ALD system according to claim 5, wherein each said bypass line includes therein an isolation valve which is controlled for an opening/closing state thereof depending on the pressure measured by said second vacuum gauge.

7. The in-line ALD system according to claim 6, wherein a flow of a vapor phase reactant is controlled by using said pressure-control rotary valves while closing each said isolation valve during a depositing time interval for depositing the film by using the ALD process, and each said isolation valve is opened to discharge the gas by using said bypass line during a time interval other than said depositing time interval.

8. The in-line ALD system according to claim 7, wherein the open angle of each said pressure-control rotary valve is changed to an optimum angle to be used for a subsequent time interval, while discharging the gas by opening each said isolation valve and using each said bypass line.

9. A method for depositing an insulation film by using an in-line atomic layer deposition (ALD) system including a reaction chamber, a stage arranged in said reaction chamber for mounting thereon a semiconductor wafer, and a plurality of exhaust tubes provided on a periphery of said stage, said exhaust tubes each including therein a control valve for adjusting the exhaust volume and a first vacuum gage arranged at upstream of said control valve for measuring a degree of vacuum in a corresponding one of said exhaust tubes, said method comprising the steps of:
alternately introducing a plurality of vapor phase reactants into said reactor chamber;
controlling said exhaust tubes in an exhaust volume thereof independently from one another by using said control valve during evacuation of at least one of the vapor phase reactants; and
controlling an open angle of each said control valve depending on a pressure measured by each said first vacuum gauge, to thereby control a direction of flow of said vapor phase reactant in said reaction chamber.

10. The method of depositing an insulation film according to claim 9, wherein preparation of a process condition for depositing the insulation film includes the step of optimizing an open angle of each said control valve to equalize the flow of the vapor phase reactant in each deposition step of the ALD process.

11. The method of depositing an insulation film according to claim 10, wherein a gas to be fed into the reaction chamber in the procedure for optimizing the open angle of each said control valve is identical to the vapor phase reactant used for forming the actual film.

12. The method of depositing an insulation film according to claim 10, wherein a gas to be fed into the reaction chamber in the procedure for optimizing the open angle of each said control valve is an arbitrary gas linked to said deposition system.

13. The method of depositing an insulation film according to claim 10, wherein, in a deposition time interval of the insulation film, the optimum open angle determined in the procedure for optimizing the open angle of each said control valve is used as a setup parameter of the open angle for each step, and the open angle of each said control valve is changed in accordance with a timing at which each step is switched over to a next step.

14. The method of depositing an insulation film according to claim 10, wherein, in a deposition time interval of the insulation film, the open angle of each said control valve is controlled by using a pressure measured by a second vacuum gauge arranged in said reaction chamber and the pressure measured by each said first vacuum gauge, in accordance with a timing at which each step is switched over to a next step.

15. The method of depositing an insulation film according to claim 10, wherein, in a deposition time interval of the insulation film, the optimum open angle determined in the procedure for optimizing the open angle of each said control valves is used as a setup parameter of the open angle for each step, and the open angle of each said control valve is changed to an optimum angle in accordance with a timing at which each step is switched over to a next step, and thereafter, the open angle of each said control valve is controlled by using a pressure measured by a second vacuum gauge arranged in said reaction chamber and the pressure measured by said first vacuum gauges.

16. The method of depositing an insulation film according to claim 10, wherein change of the open angle of each said control valve used in a deposition time interval of the insulation film is performed in a step which does not deposit the insulation film.

17. The method of depositing an insulation film according to claim 10, wherein the change of the open angle of each said control valve used in a deposition time interval of the insulation film is performed in steps before or after the steps which do not deposit the insulation film.

18. The method of depositing an insulation film according to claim 10, wherein the open angle of each said control valve in the step which does not deposit the insulation film is set to be fully open.

19. The method of depositing an insulation film according to claim 10, wherein the open angle of each said control valve in the step which does not deposit the insulation film is set to the optimum open angle for the subsequent step.
